(19) United States
(12) Patent Application Publication
(10) Pub. No.: US 2006/0157722 A1
(43) Pub. Date: Jul. 20, 2006

(54) Semiconductor light emitting device

(75) Inventors: Hatsuo Takezawa, Kanagawa-ken (JP); Shinichi Inagaki, Kanagawa-ken (JP); Tetsuro Komatsu, Kanagawa-ken (JP); Takeshi Miyakawa, Hyogo-ken (JP); Atsuo Inoue, Kanagawa-ken (JP); Tsubasa Kusaka, Kanagawa-ken (JP); Fujio Takahashi, Kanagawa-ken (JP)

Correspondence Address: BANNER & WITCOFF, LTD., ATTORNEYS FOR RESERVE;ATTORNEYS FOR CLIENT NO. 000449, 001701, 1001 G STREET, N.W., 11TH FLOOR, WASHINGTON, DC, 20001-4597, US

(73) Assignee: Kabushiki Kaisha Toshiba, Tokyo (JP)

(21) Appl. No.: 11/293,358

(22) Filed: Dec. 5, 2005

(30) Foreign Application Priority Data
Dec. 3, 2004 (JP) 2004-351921
Apr. 8, 2005 (JP) 2005-112345

(51) Int. Cl. H01L 33/00

(52) U.S. Cl. 257/98

(57) ABSTRACT

Various semiconductor light emitting devices are described. In one aspect, the semiconductor light emitting device may include, an insulating substrate having an electrode pattern; a metal body provided on the insulating substrate, the metal body having a through-hole; an adhesive layer provided between the insulating substrate and the metal body; a semiconductor light emitting element provided in the through-hole of the metal body, provided on the insulating substrate and electrically connected to the electrode pattern; and a resin configured to seal the semiconductor light emitting, wherein an inner surface of the through-hole faces the semiconductor light emitting element. The inner surface may have a slanted surface and at least a part of the light emitted from the semiconductor light emitting element reflected by the inner surface.

### CROSS REFERENCE TO RELATED APPLICATION

This application is based upon and claims the benefit of priority from Japanese Patent Application No. 2004-351921, filed on Dec. 3, 2004 and Japanese Patent Application No. 2005-112345, filed on Apr. 8, 2005, the entire contents of both applications are incorporated herein by reference.

### BACKGROUND OF THE INVENTION

An SMD (Surface Mount Device) is used as a semiconductor light emitting device since a high density packaging or a good heat releasing is required for the light emitting device. The SMD is mounted on a circuit board with reflow process using a Pb free solder. In a conventional SMD-type semiconductor light emitting device, a light emitting element (LED chip) is surrounded by a resin which has a reflection layer on the inner surface, and the light emitted from the LED chip is reflected toward outside by the reflection layer. The reflection layer is made of a metal deposited layer, which has high reflective index such as Al. In other words, the reflection surface is a deposited layer which is provided on the resin.

However, the melting point of the Pb free solder is higher than that of a conventional Pb solder. The melting point of the Pb free solder is about 250-260 Centigrade. This can result in cracks forming in the deposited layer or the surface of the reflection layer being roughened after the reflow process.

### SUMMARY

In one aspect of the present invention, the semiconductor light emitting device may include, an insulating substrate having an electrode pattern; a metal body provided on the insulating substrate, the metal body having a through-hole; an adhesive layer provided between the insulating substrate and the metal body; a semiconductor light emitting element provided in the through-hole of the metal body, provided on the insulating substrate and electrically connected to the electrode pattern; and a resin configured to seal the semiconductor light emitting, wherein an inner surface of the through-hole faces the semiconductor light emitting element, the inner surface has a slanted surface and at least a part of the light emitted from the semiconductor light emitting element is configured to be reflected by the inner surface.

In another aspect of the present invention, the semiconductor light emitting device may include, an insulating substrate having an electrode pattern; a metal body provided on the insulating substrate, the metal body having a through-hole; an adhesive layer provided between the insulating substrate and the metal body; a semiconductor light emitting element provided in the through-hole of the metal body, provided on the insulating substrate and electrically connected to the electrode pattern; and a resin configured to seal the semiconductor light emitting, wherein an inner surface of the through hole faces the semiconductor light emitting element, the inner surface of the through-hole has a first slanted surface and a second slanted surface, the second slanted surface is larger in an angle from the than the first slanted surface, and at least a part of the light emitted from the semiconductor light emitting element is configured to be reflected by the inner surface.

In yet another aspect of the present invention, the semiconductor light emitting device may include, an insulating substrate having an electrode pattern; a metal body provided on the insulating substrate, the metal body having a through-hole; an adhesive layer provided between the insulating substrate and the metal body; a semiconductor light emitting element provided in the through-hole of the metal body, provided on the insulating substrate and electrically connected to the electrode pattern; and a resin configured to seal the semiconductor light emitting, wherein an inner surface of the through-hole faces the semiconductor light emitting element, the inner surface of the through-hole has an downward convex envelope in a cross sectional view and at least a part of the light emitted from the semiconductor light emitting element is configured to be reflected by the slanted surface.

### BRIEF DESCRIPTIONS OF THE DRAWINGS

FIG. 1 is a schematic cross sectional view of a semiconductor light emitting device in accordance with a first embodiment of the present invention.

FIG. 2 is a schematic cross sectional view of a semiconductor light emitting device in accordance with a comparative example.

FIG. 3A is a graph showing a directivity of a semiconductor light emitting device in accordance with a first embodiment and a semiconductor light emitting device of the comparative example. FIG. 3B is a schematic top view of a semiconductor light emitting device.

FIG. 4 is a schematic overview of assembling an insulating substrate for multiple units and metal body for multiple units.

FIG. 5 is a flow chart for manufacturing process of the semiconductor light emitting device in accordance with a first embodiment.

FIGS. 6, 7 and 8 are schematic views showing a dicing process of the manufacturing process in accordance with the first embodiment.

FIG. 9 is a flow chart for manufacturing process of the semiconductor light emitting device in accordance with a first embodiment.

FIGS. 10, 11 and 12 are schematic views showing a dicing process of the manufacturing process in accordance with the first embodiment.

FIGS. 13A-H are schematic cross sectional views of the manufacturing process of a metal body by press forming.

FIGS. 14A and 14B are schematic cross sectional views of the manufacturing process for metal body by precision cutting.

FIG. 15 is a schematic cross sectional view of the manufacturing process for metal body by milling.

FIGS. 16A and 16B are schematic cross sectional view of a semiconductor light emitting device in accordance with a modified embodiment of the present invention.

FIG. 17 is a schematic cross sectional view of a semiconductor light emitting device in accordance with a second embodiment of the present invention.

FIG. 18 is a schematic cross sectional view of a semiconductor light emitting device in accordance with a third embodiment of the present invention.

FIG. 19 is a schematic cross sectional view of a semiconductor light emitting device in accordance with a fourth embodiment of the present invention.

FIG. 20 is a schematic cross sectional view of a semiconductor light emitting device in accordance with a fifth embodiment of the present invention.

FIG. 21 is a schematic cross sectional view of a semiconductor light emitting device in accordance with a sixth embodiment of the present invention.

FIG. 22 is an enlarged view of “F” in FIG. 21.

FIG. 23 is a graph showing a relationship a relative luminosity (Y axis) and a distance between a metal body and an active layer (X-axis).

FIG. 24 is a flow chart for manufacturing process of the semiconductor light emitting device in accordance with a sixth embodiment.

FIG. 25 is a top view of a semiconductor light emitting device in accordance with a sixth embodiment.

FIG. 26 is a bottom view of a semiconductor light emitting device in accordance with a sixth embodiment.

FIG. 27 is a schematic side view of a semiconductor light emitting device in accordance with a sixth embodiment.

FIG. 28 is a schematic cross sectional view of a metal body in accordance with a seventh embodiment of the present invention.

FIG. 29 is a schematic bottom view of a metal body of FIG. 28.

FIG. 30 is a schematic top view of an insulating substrate in accordance with a seventh embodiment of the present invention.

FIG. 31 a cross sectional view of a semiconductor light emitting device in accordance with a seventh embodiment of the present invention.

### DETAILED DESCRIPTION OF THE INVENTION

Various connections between elements are hereinafter described. It is noted that these connections are illustrated in general and, unless specified otherwise, may be direct or indirect and that this specification is not intended to be limiting in this respect.

Embodiments of the present invention will be explained with reference to the drawings as follows.

### First Embodiment

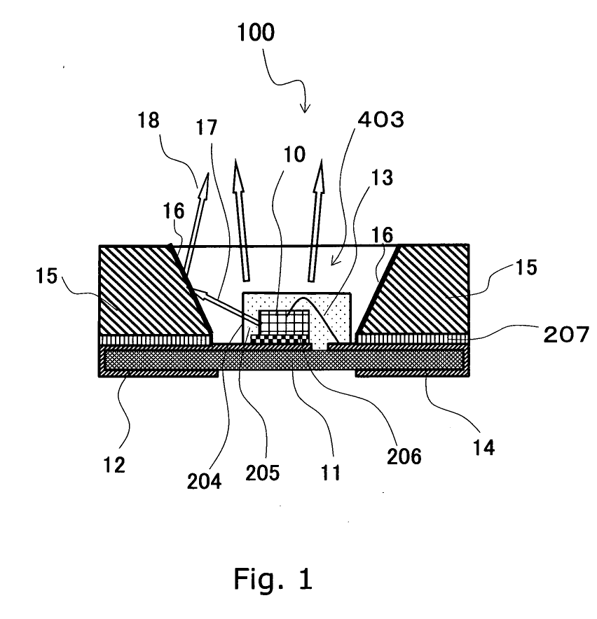

FIG. 1 is a schematic cross sectional view of a semiconductor light emitting device in accordance with a first embodiment of the present invention. A semiconductor light emitting device 100 is shown in FIG. 1.

A semiconductor light emitting element 10 (abbreviated LED chip 10) is configured to emit ultra violet light or longer wavelength light. The LED chip 10 is mounted on a first electrode pattern 12 of an insulating substrate 11 with an AuSn eutectic solder 206. The melting point of the AuSn eutectic solder 206 is about 280 Centigrade. An electrode, which is provided on a top surface of the LED chip 10, and a second electrode pattern 14 are electrically connected by a wire 13. The LED chip 10 and the wire 13 are sealed by a resin 204. The substrate 11 may be AlN, which has a good heat releasing. A ceramic, an Al₂O₃, or a printed circuit board which a heat extraction member is pressed in the substrate 11.

The LED chip 10 may be a chip provided on an insulating substrate, including but not limited to a sapphire substrate. In this case, the electrodes (p side and n side electrodes) may be provided on a top surface of the LED chip 10. The electrodes of the LED chip 10 may be connected to the first electrode pattern 12 and the second electrode pattern 14 with a wire 13 respectively.

As shown in FIG. 1, a metal body 15 having a through-hole 403 is provided on the insulating substrate 11 such that the resin 204 is provided in the through-hole 403. The metal body 15 and the insulating substrate 11 are adhered by an adhesive layer 207. For example, the adhesive layer 207 may be an insulating adhesive sheet, which can have an adhesive on both surfaces. The adhesive sheet may be an epoxy resin. An insulating adhesive may be used as the insulating layer 207.

The adhesive layer 207 is durable in reflow process of 260 Centigrade. A slanted surface can be provided on the inner surface of the through-hole 403. A slanted surface can function as a reflector. Light 17 emitted from the LED chip 10 toward horizontal direction are reflected by the reflection surface 16. Light 18 reflected by the reflection surface 16 is mixed with light emitted directly upward from the LED chip 10. The reflection surface 16 shown in FIG. 1 is a line shaped, however the reflection surface is not limited to this. The reflection surface 16 may be a curve shape in a cross sectional view. It may be preferable that the reflection surface 16 is mirror surface.

A directivity of light emitted from the semiconductor light emitting device 100 is controlled by the reflection surface 16. The metal body 15 may be made of Al, Ag, Cu plated by Au and so on. An Al is preferable in the aspect of the endurance, productivity and cost. Alternatively the reflection surface 16 may be made of a metal layer which is different in material from the metal body 15. Namely a different metal may be provided on the metal body 15. Ag or Rh may be provided on the metal body 15. These metals have a relatively good index of reflection in blue light.

White light is obtained by mixing a fluorescent material 205, which absorbs light from the LED chip 10 and emits converted light. For example, a GaN based blue light emitting diode is used as the LED chip 10 and the fluorescent material 205 (in this case a yellow phosphor) is provided in the resin 204. So white light which is mixed by blue light emitted from the LED chip 10 and yellow light converted by the fluorescent material 205 are emitted from the semiconductor light emitting device 100. White light may be obtained by ultraviolet LED chip 10 and RGB phosphors.

The resin 204 may be an epoxy resin or a silicone resin. The silicone resin (refractive index: about 1.4) is preferable in case the LED chip 10 emits ultraviolet light to blue light.

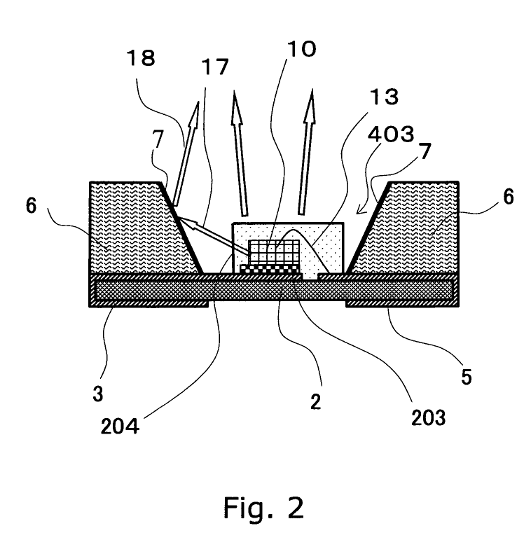

A comparative example is explained. FIG. 2 is a schematic cross sectional view of a semiconductor light emitting device in accordance with a comparative example. With respect to each portion of this comparative example, the same or corresponding portions of the semiconductor light emitting device of the first embodiment shown in FIG. 1 are designated by the same reference numerals, and its explanation of such portions is omitted.

In this comparative example, the LED chip 10 is mounted with an Ag paste 203 on a first electrode pattern 3 of a print substrate 2. An upper electrode of the LED chip 10 electrically connected by the wire 13 to the second electrode pattern 5 of the print substrate 2. The LED chip 10 and the wire 13 are sealed by the resin 204.

An injection mold resin 6 is provided around the resin 204 such that the resin 204 is provided in the through-hole 403. An Al deposited layer 7 is provided on an inner surface of the injection mold resin 6. So the Al deposited layer 7 is functioned as a reflection surface. The injection mold resin 6 may be a white resin such as polyphthalamide (PPA). The thermal expansion ratio of the thermoplastic resin is about 100 ppm/Centigrade. However, the thermal expansion ratio of the Al is about 20 ppm/Centigrade. The reflow process of Pb free solder is more than 250-260 Centigrade. So small cracks or fine protrusions and depressions can appear on the Al deposited layer 7 on the injection mold resin. The reflection index of the reflection layer 7 is, thus, not stable.

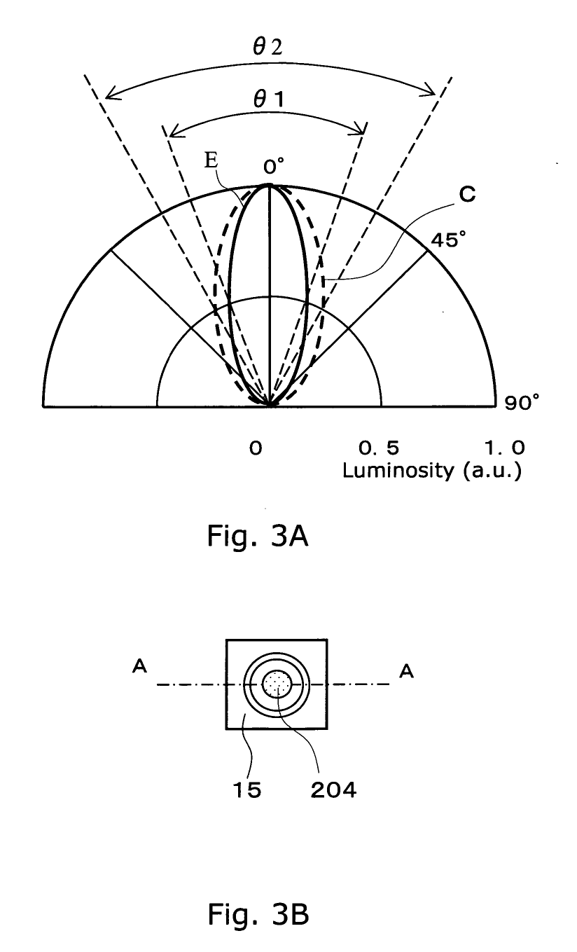

FIG. 3A is a graph showing a directivity of a semiconductor light emitting device in accordance with a first embodiment and a semiconductor light emitting device of the comparative example. FIG. 3B is a schematic top view of a semiconductor light emitting device.

In this comparative example, a directivity before reflow process is shown as “E” in FIG. 3A and half luminosity angle is about 50 degree (θ₁). Generally a required half luminosity angle of light source for flashlight is about 50 degree (Θ₁). However, after a reflow process is operated to the semiconductor light emitting device of the comparative example, the directivity is changed to “C” in FIG. 3B and the half luminosity angle is changed to about 70 degree (θ₂). Furthermore, the reflective index is worsened in the comparative semiconductor light emitting device and the axial luminosity is reduced 30% after the reflow process. In this case, half luminosity angle is defined as an angle where luminosity is 50% of axial luminosity.

However, it is hard for the semiconductor light emitting device of the first embodiment, the directivity is changed, even after the reflow process. Namely, half luminosity angle is about 50 degree (θ₁) and a change before and after the reflow process (250-260 Centigrade) is quite small.

A difference in a thermal expansion rate between the reflection surface 16 and the metal body is quite small in this embodiment. So the reflection surface 16 of this embodiment is damaged less than that of the comparative example.

The injection mold resin 6 of this comparative example is made by injection molding. Manufacturing time for a metal mold of the injection mold resin 6 is about some months, which are too long of a period for an early replacement product such as flashlight for cellular phone.

The print substrate 2 of this comparative example has a high heat conduction rate, 1.5 Centigrade/mK. When the driving current of the comparative semiconductor light emitting device is increased up to 20 mA, the efficiency (luminosity/current) is decreased about 20% with comparing to driving at 10 mA.

However, in this first embodiment, the efficiency is not worsened in 20 mA driving current and is decreased equal to or less than 5% in 30 mA driving current. So a high power semiconductor light emitting device is obtained. The reason may be supposed that the semiconductor light emitting device 100 of this first embodiment has a low heat resistance and a linearity of the optical output-driving current. The semiconductor light emitting device 100 is capable of be added large current.

In the semiconductor light emitting device of this first embodiment the LED chip 10 can be mounted by a AuSn eutectic solder (heat conductivity: 2-40 Centigrade/mK) which can endure in a high temperature mounting process, although the LED chip is mounted Ag paste (heat conductivity: 2-40 Centigrade/mK), in the semiconductor light emitting device of comparative example. Furthermore, the operating temperature range is broadened. When Au is used as the electrode pattern 12, 14 of the insulating substrate 11, it is preferable that AuSn solder having 30% Sn as its composition rate is used as the AuSn eutectic solder 206.

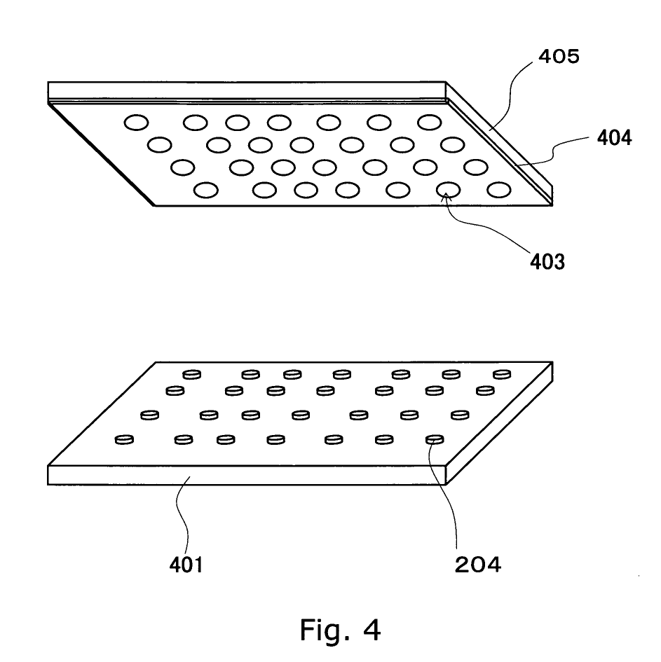

A manufacturing process of the semiconductor light emitting device of the first embodiment will be explained hereinafter with reference to FIGS. 4-15.

The metal body 15 may be made by a press forming, a precision cutting or a metal injection molding process. A material for multiple units may be effective in the aspect of manufacturing efficiency.

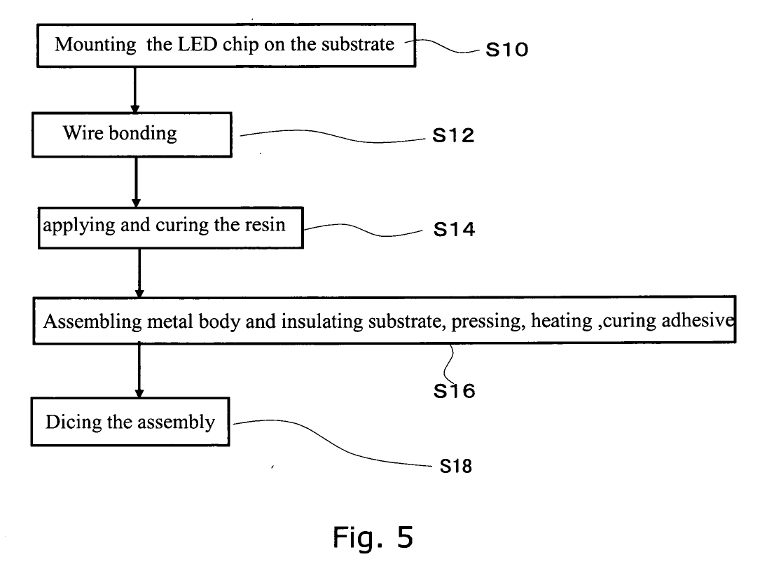

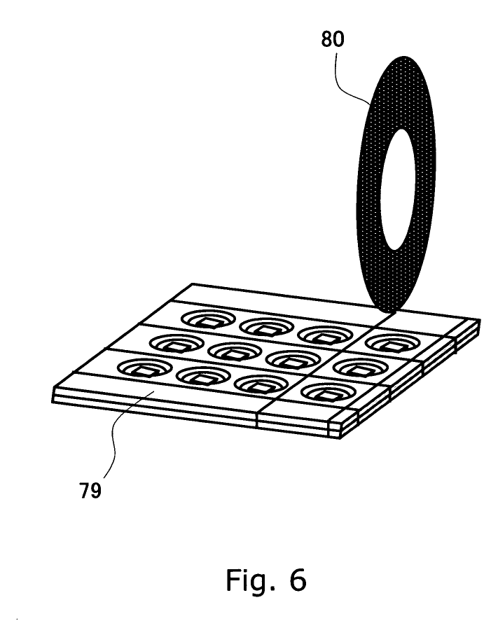

FIG. 4 is a schematic overview of assembling an insulating substrate for multiple units and metal body for multiple units. FIG. 5 is a flow chart for manufacturing process of the semiconductor light emitting device in accordance with a first embodiment. FIG. 6 is a schematic view showing a dicing process of the manufacturing process in accordance with the first embodiment.

Step S10.

The LED chip 10 is mounted on an insulating substrate for multiple units 401.

Step S12.

The LED chip 10 and the electrode pattern of the insulating substrate for multiple units 401 are wire-bonded by a wire (not shown in FIG. 4).

Step S14.

The resin 204 is applied on the LED chip 10 and cured. Meanwhile a metal body for multiple units 405 has a plurality of through-holes 403 having slanted surface. An adhesive sheet 404 having a through-hole corresponding to the through-hole 403 is attached on the metal body for multiple units 405. The metal body for multiple units 405 may be Al sheet. The thickness of the metal body for multiple units 405 may be 0.5-3 mm, preferably 0.7-1.5 mm. The adhesive sheet 404 may be epoxy based adhesive sheet.

Step S16.

The insulating substrate for multiple units 401 and the metal body for multiple units 405 are adhered with interposing the adhesive sheet 404. The thickness of the adhesive sheet 404 after pressing, heating and curing is about 0.05 mm. For example, the curing condition is 30 minutes in 150 Centigrade. The assembly 79 is created.

Step S18.

As shown in FIGS. 6-8, the assembly 79 is fixed on a plate 84 of a dicer. The assembly 79 is separated by the dicing blade 80.

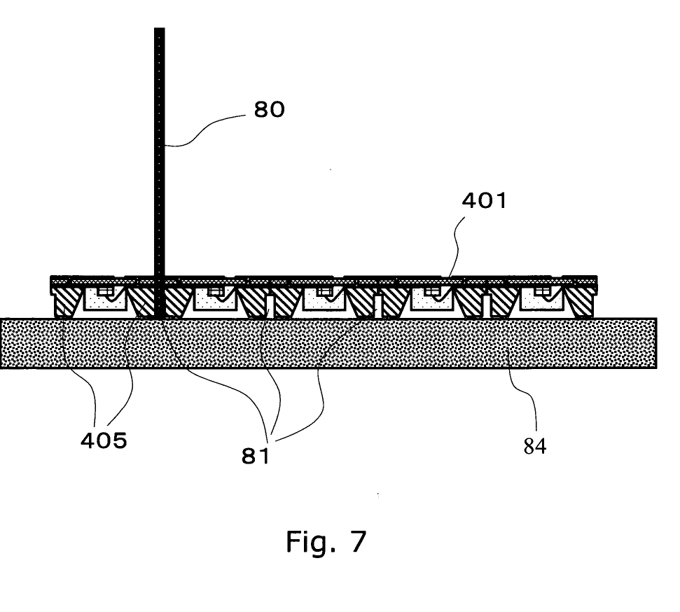

In FIG. 7, a trench 81 is provided on the metal body for multiple units 405. In case the thickness of the metal body for multiple units 405 is about 1.2 mm, it takes longer operating time for dicing. However, the manufacturing efficiency is improved by the trench 81, since the dicing time is shortened.

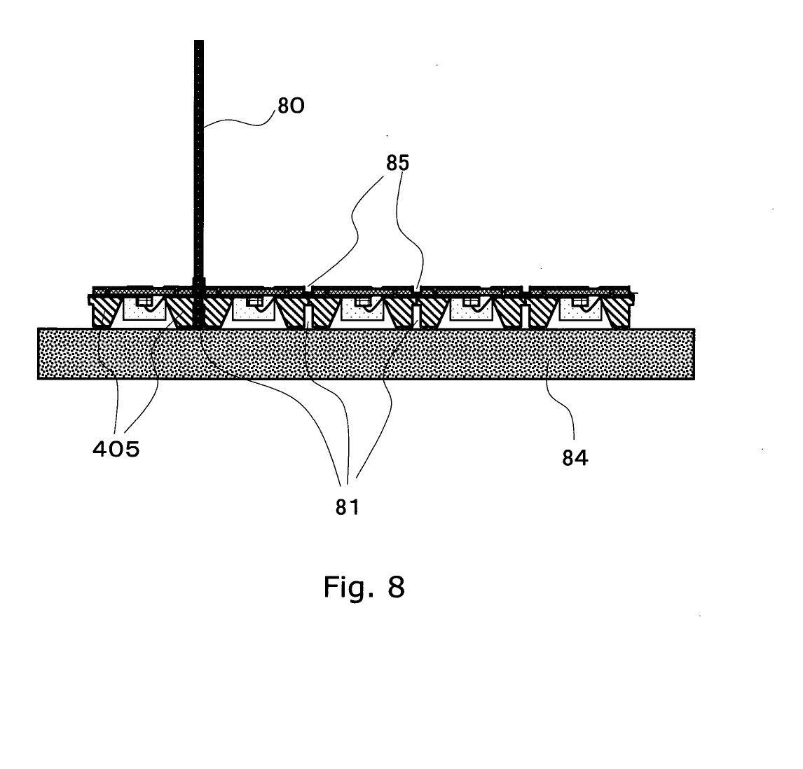

As shown in FIG. 8, the dicing time is also shortened by a trench 81, 85 in the insulating substrate 401.

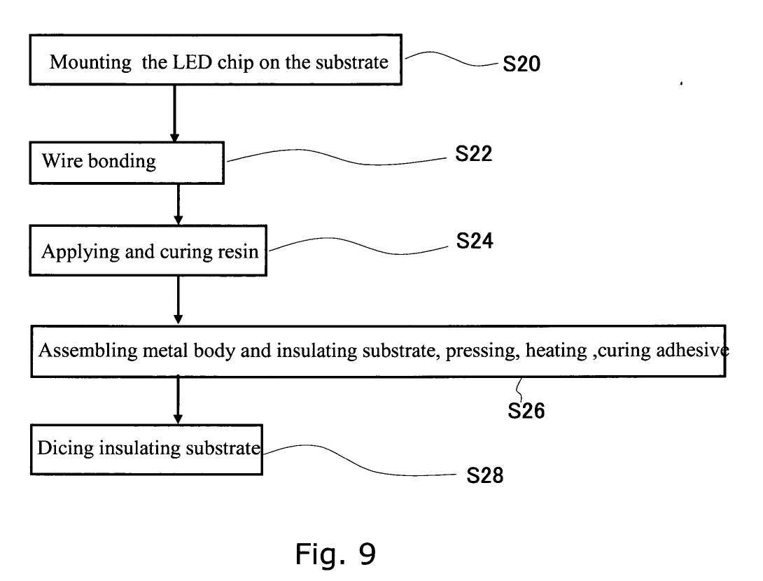

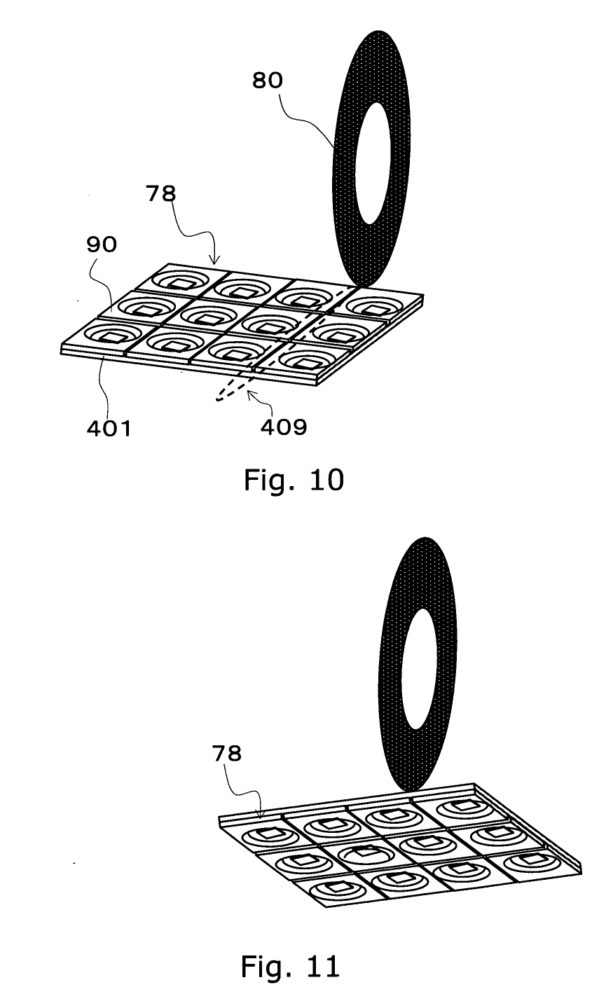

FIG. 9 is a flow chart for manufacturing process of the semiconductor light emitting device in accordance with a first embodiment. FIGS. 10, 11 and 12 are schematic views showing a dicing process of the manufacturing process in accordance with the first embodiment.

During a process as shown in FIG. 9, an insulating substrate is the insulating substrate for multiple units 401. However, the metal body for multiple units 405 as shown in FIG. 4 is not used.

Step S20, chip mounting, Step S22, wire-bonding, Step S24 applying and curing are corresponding respectively to Step S10, Step S12, Step S24 as shown in FIG. 5 respectively. The metal body 15 is not for multiple units in this case. An individual metal body 90 is used.

Step S26.

The individual metal body 90 is made individually by a press forming or a high speed precision cutting, which has a good manufacturing efficiency. The individual metal body 90 is adhered on the insulating substrate for multiple units 401. Pressing, heating and curing the adhesive sheet 404 is operated and an assembly 78 is created. Manufacturing efficiency by using individual metal body 90 is not worse than by using the metal body for multiple units 405, since adjusting the individual metal body 15 with the insulating substrate 401 may be automated.

Step S28.

The assembly 78 is separated by the dicing blade 80. When the assembly 78 may be cut along a region where the individual metal body 90 is not provided, as shown in FIG. 10, a loss, which is cut by the dicing blade 80, is reduced. The assembly 78 may be cut from the back side of the insulating substrate for multiple units 401. It is preferable that the blade 80 does not contact the individual metal body 90.

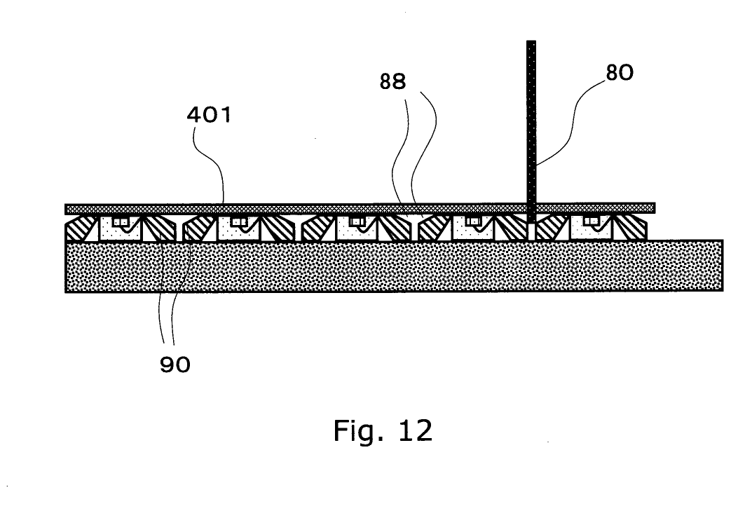

As shown in FIG. 12, a depression 88 may be provided in the back side of the individual metal body 90. Near the peripheral portion, in top view, of the metal body 90, the metal body 90 does not contact the insulating substrate for multiple units 401. The depression 88 may be made shaving or chamfering the surrounding of the metal body 90. The blade 80 does not contact or barely contacts or the metal body 90 because of the presence of depression 88.

In case the large ceramic substrate is used as an insulating substrate 2, it is preferable the insulating substrate for multiple units 401 is used as insulating substrate.

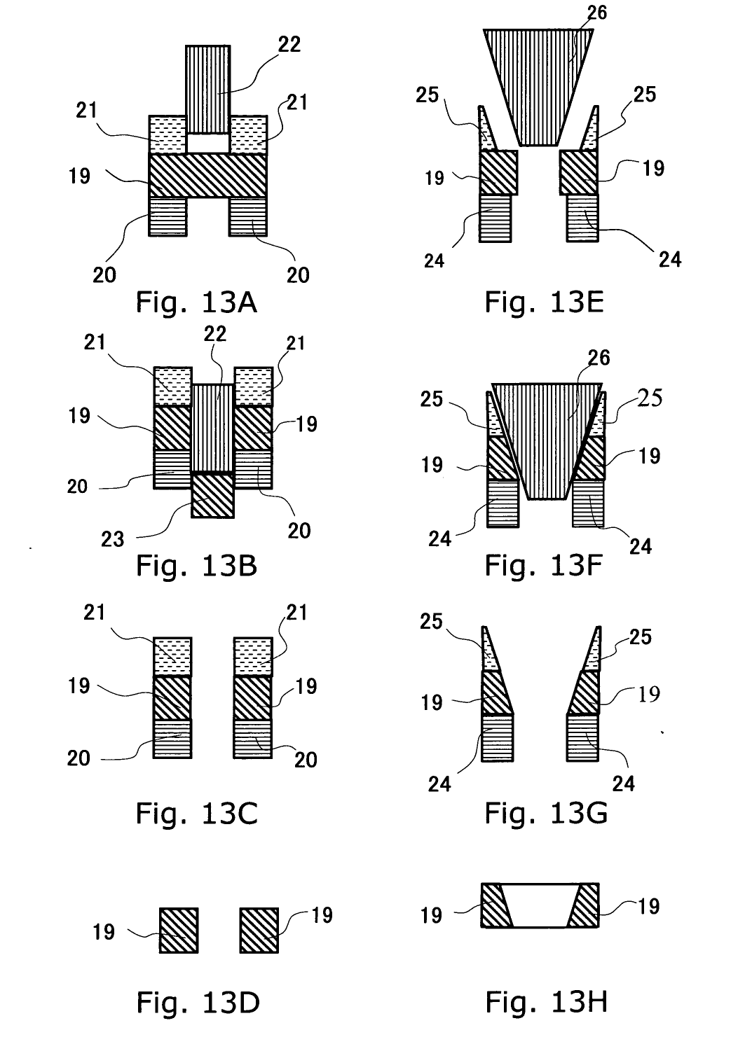

A manufacturing process of the metal body 15 is explained hereinafter with reference to FIGS. 13A-H. FIGS. 13A-H are schematic cross sectional views of the manufacturing process for metal body by a press forming.

As shown in FIG. 13A, the metal board 19 is fixed with a drilling die 20 and a drilling stripper 21.

As shown in FIG. 13B, a hole is formed in a center portion 23 of the metal board 19 by a drilling punch 22.

As shown in FIG. 13C, the drilling punch 22 is removed.

As shown in FIG. 13D, the drilling die 20 and the drilling stripper 21 are removed from the metal board 19.

As shown in FIG. 13E, the metal board 19 is fixed with a die 24 and stripper for slanted surface 25.

As shown in FIG. 13F, the metal board 19 is deformed in plasticity by a punch for slanted surface 26. A slanted surface is formed in the metal board 19. The slanted surface of the metal board 19 is substantially equal in angle to the punch 26.

As shown in FIG. 13C the punch 26 is removed.

As shown in FIG. 13H, the die 24 and the stripper 25 are removed from the metal board 19. The die 20, the stripper 21, the punch 22, the die 24, the stripper 25 and the punch 26 may be a hard metal or other hard material (including but not limited to ceramics).

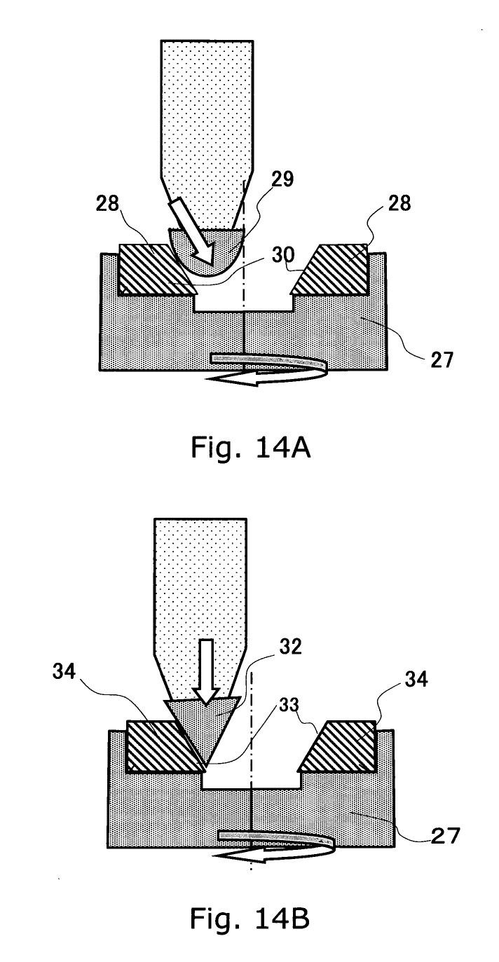

FIGS. 14A and 14B are schematic cross sectional views of the manufacturing process for a metal body by a precision cutting process. In FIGS. 14A, 14B, the metal body 15 is formed by a turning during the precision cutting process.

As shown in FIGS. 14A, a metal board 28 is chucked by a spindle axis 27 (turning axis) of a turning machine. A slanted surface 30 of the metal board 28 is formed by a byte 29, which can be made of a single crystal diamond and attached to a table of the turning machine. The chucked metal board 28 is turned on its axis.

As shown in FIG. 14B, a byte may have a shape which is substantially incident to a slanted surface 33 of a metal board 34.

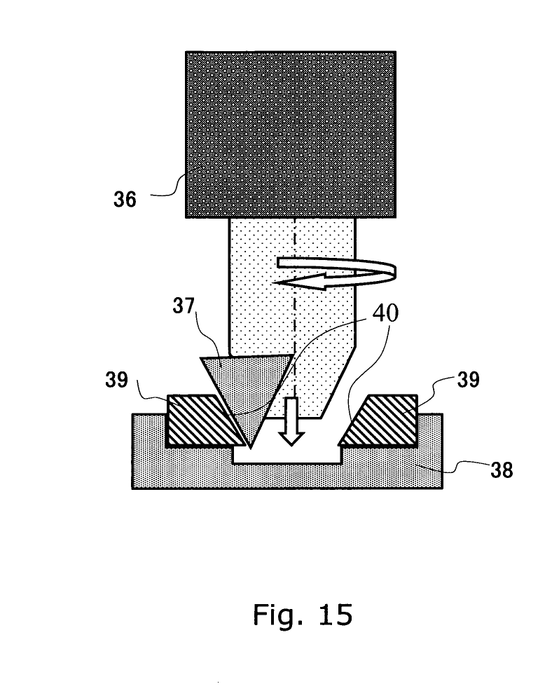

FIG. 15 is a schematic cross sectional view of the manufacturing process for metal body by a milling process.

As shown in FIG. 15, a metal board is chucked by a table 38 of the milling machine. A slanted surface 40 is formed by an end mill 37 which blade is made of a single crystal diamond and attached to a spindle axis 36 of the milling machine. The spindle axis 36 is turned on its axis.

A metal body 15, which has a good roughness on the slanted surface, may be formed such as by a metal injection process.

Generally, if the slanted surface of the metal body is rough, light is scattered and the directivity of light may be deviated from a designed value. In a light emitting device where half luminosity angle is 50 degree with the surface roughness (Rz) of reflection surface being no more than 100 nm, half luminosity angle is worsened to about 65 degree in the same slanted angle if the surface roughness (Rz) is 300 nm.

However, when the metal body 15 is manufactured as shown FIGS. 13-15, the semiconductor light emitting device has a good surface roughness in its reflection surface.

Long term reliability of the metal body will be explained. In this case, the metal body is made of Al.

In case an Al reflection surface is set for a long hour in high temperature and high humidity (85 Centigrade, 85% RH), the Al reflection surface has a crack and a white portion which causes a worsening of reliability or directivity. This may be improved by increasing the Al purity equal to or higher than 99.9%.

According to a sample test, in case an A5056 alloy (Al: 94.6%, Mg: 4.7%, other(s): 0.7%) is used as the metal body 15, the luminosity worsens about 20% from an initial value after passing 168 hours in high temperature high humidity (85 Centigrade, 85% RH). However in case a 99.9% pure Al is used as the metal body 15, the luminosity is rarely worsened after the same test.

An Al oxide layer, TiO2 or organic transparent layer may be formed on the reflection for improving humidity resistance.

### A Modified Embodiment of the First Embodiment

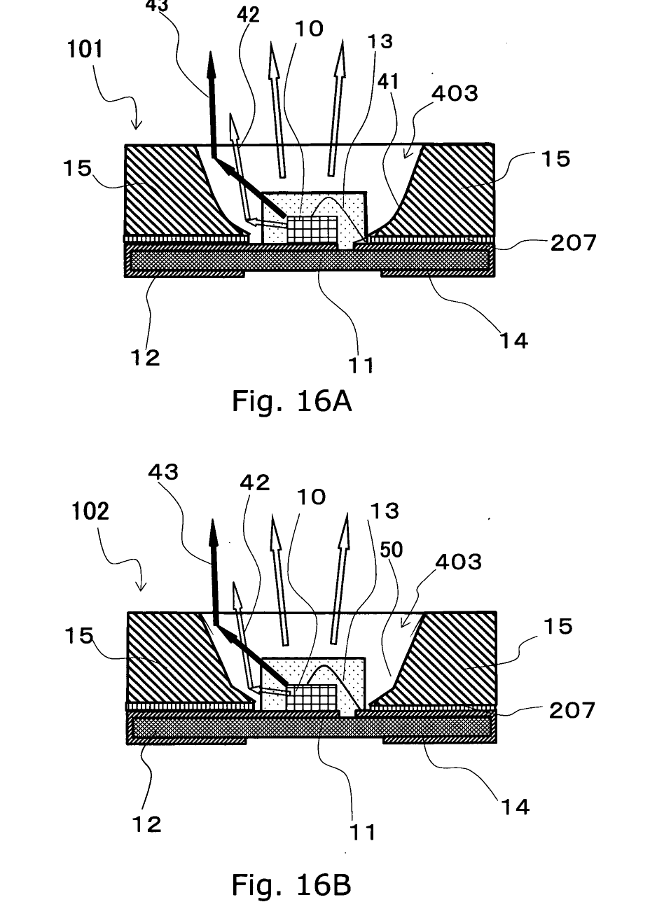

A modified embodiment of the first embodiment will be explained hereinafter with reference to FIGS. 16A and 16B.

A semiconductor light emitting device 101 is described in accordance with this modified embodiment of the present invention. With respect to each portion of this embodiment, the same or corresponding portions of the semiconductor light emitting device of the first embodiment as shown in FIGS. 1-15 are designated by the same reference numerals, and its explanation of such portions is omitted.

As shown in FIG. 16A, the inner surface 41 of the metal body 15 has a curved surface. In the cross sectional view like FIG. 16A, the inner surface 41 is a shaped downward convex envelope. A slope of a tangent of the inner surface 41 is small in a lower part (near part from the LED chip 10) of the inner surface 41 and large in an upper part (far part from the LED chip 10) of the inner surface 41. The downward convex envelope may be a parabola.

A direction of light 42 which is reflected by the lower part of the inner surface 41 and a direction of light 43 which is reflected by the upper part of the inner surface 41 may be coincident with light emitted directly from LED chip 10. The directivity of the semiconductor light emitting device 101 may be improved.

As shown in FIG. 16B, an inner surface 50 of the metal body 15 is composed of two angle slanted surface. An angle of the inner surface 50 is small in a lower part (near part from the LED chip 10) of the inner surface 50 and large in an upper part (far part from the LED chip 10) of the inner surface 50.

As shown in FIGS. 16A, 16B, an envelope of the inner surface which is composed of curved line or straight line may be downward convex. So the directivity is improved to be suitable for flashlight use, for instance.

It may be preferable for improving half luminosity full angle in directivity that the sealing resin 204 is smaller than the through-hole 403. Alternatively the through-hole 403 may be filled with the sealing resin 204. Furthermore, a plurality of LEDs may be provided in single semiconductor light emitting device.

A GaN based blue light semiconductor light emitting element may be used as the LED chip 10 and a fluorescent material 205 which transfers from blue to yellow may be dispersed in sealing resin 204.

### Second Embodiment

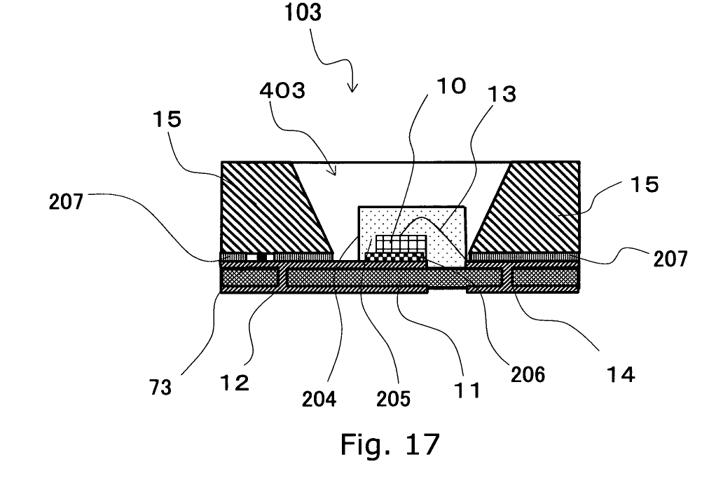

A second embodiment of the present invention will be explained hereinafter with reference to FIG. 17. FIG. 17 is a schematic cross sectional view of a semiconductor light emitting device in accordance with the second embodiment.

A semiconductor light emitting device 103 is described in accordance with this second embodiment of the present invention. With respect to each portion of this embodiment, the same or corresponding portions of the semiconductor light emitting device of the first embodiment or its modified embodiment as shown in FIGS. 1-16 are designated by the same reference numerals, and its explanation of such portions is omitted.

The metal body 15 may be charged during a manufacturing process. Generally the light emitting element (LED chip) has smaller ESD resistance than the silicon device.

In this second embodiment, the metal body 15 is electrically connected via a bump 73 with one of the first electrode 12 and the second electrode 14 of the insulating substrate 11. In FIG. 17 the metal body 15 is connected to first electrode 12. When the connected electrode 12, 14 is electrically contact with the ground (GND), an ESD (Electro Static Discharge) resistance of the semiconductor light emitting device 103 is improved.

Au, Sn, In, Ag, Al or an alloy having one of them may be used as the bump 73. Au ball or solder bump may be preferable in the aspect of forming bump since they are relatively soft metal.

In case the adhesive sheet 207 is used as the adhesive between the metal body 15 and the insulating substrate 11, the bump 73 is contact with the first electrode 12 by pressing the adhesive sheet 207. The bump 73 is contact with the first electrode 12 as an under-filling of flip chip bonding. The adhesive sheet 207 has a hole in a part corresponding to the bump 73.

As mentioned above, in the semiconductor light emitting device of this second embodiment the ESD resistance is improved.

### Third Embodiment

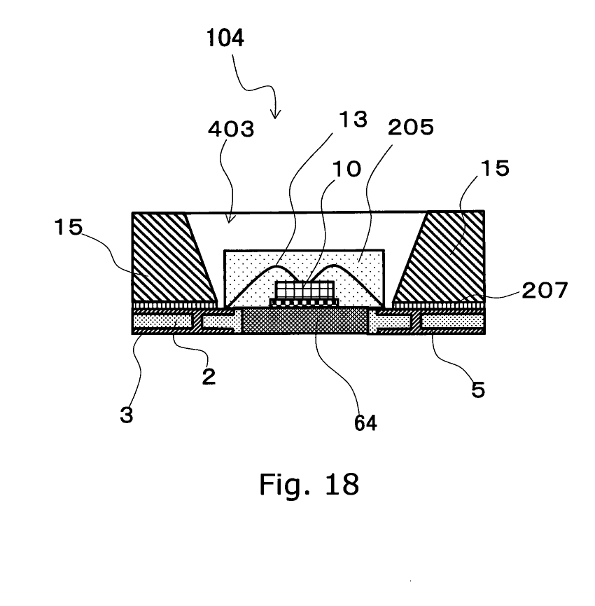

A third embodiment of the present invention will be explained hereinafter with reference to FIG. 18. FIG. 18 is a schematic cross sectional view of a semiconductor light emitting device in accordance with the third embodiment.

A semiconductor light emitting device 104 is described in accordance with this third embodiment of the present invention. With respect to each portion of this embodiment, the same or corresponding portions of the semiconductor light emitting device of the first, second embodiment or its modified embodiment as shown in FIGS. 1-17 are designated by the same reference numerals, and its explanation of such portions is omitted.

In this embodiment, a print circuit board 2 is used as the insulating substrate 11 instead of ceramic board. An electrode 3, 5 are provided on both sides (upper and lower side) of the print circuit board 2. A heat extraction member 64 can be provided in a center portion of the print circuit board 2. The LED chip 10 can be mounted on the heat extraction member 64. The metal body 15 can be provided on the print circuit board 2 via adhesive 207. Heat releasing from the LED chip 10 can be improved, the operation current range can be broadened. A high luminosity light emitting device may be obtained.

### Fourth Embodiment

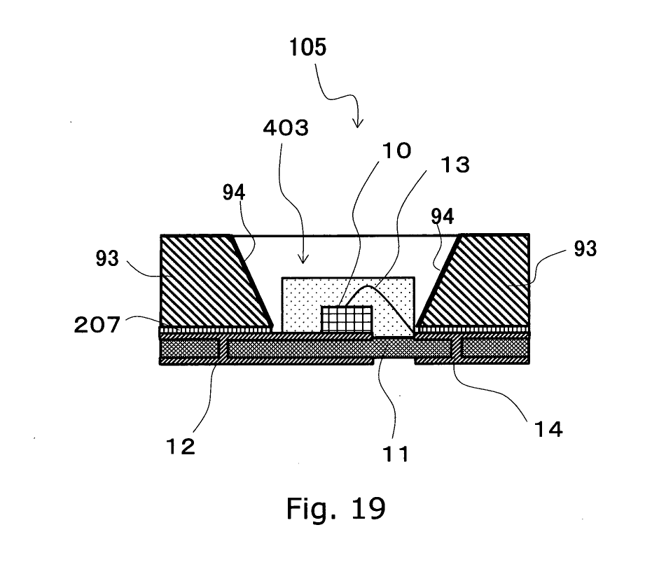

A fourth embodiment of the present invention will be explained hereinafter with reference to FIG. 19. FIG. 19 is a schematic cross sectional view of a semiconductor light emitting device in accordance with the fourth embodiment.

A semiconductor light emitting device 105 is described in accordance with this fourth embodiment of the present invention. With respect to each portion of this embodiment, the same or corresponding portions of the semiconductor light emitting device of the first, second, third embodiment or its modified embodiment as shown in FIGS. 1-18 are designated by the same reference numerals, and its explanation of such portions is omitted.

In this embodiment, a metal body 93 can be made of brass instead of Al as shown metal body 15 above. The brass is easier to form. It is preferable a reflector 94 is provided on a slanted part (inner surface) of the brass body 93. The Al reflection surface 94 may be formed by ion plating, deposition or sputtering or the like.

### Fifth Embodiment

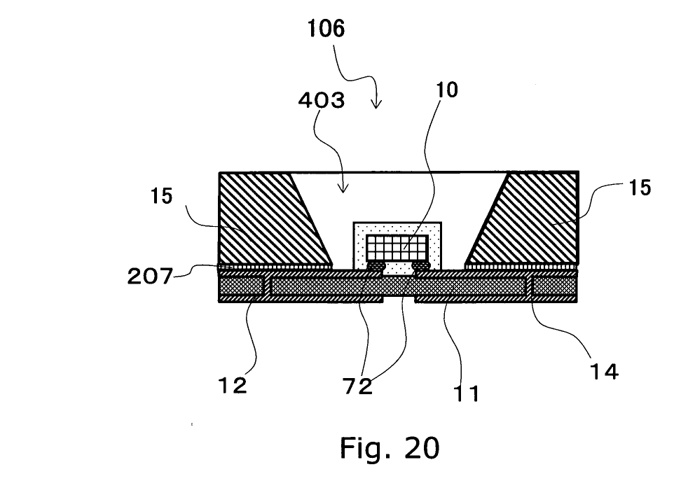

A fifth embodiment of the present invention will be explained hereinafter with reference to FIG. 20. FIG. 20 is a schematic cross sectional view of a semiconductor light emitting device in accordance with the fifth embodiment.

A semiconductor light emitting device 106 is described in accordance with this fifth embodiment of the present invention. With respect to each portion of this embodiment, the same or corresponding portions of the semiconductor light emitting device of the first, second, third, fourth embodiment or its modified embodiment as shown in FIGS. 1-19 are designated by the same reference numerals, and its explanation of such portions is omitted.

In this embodiment, the LED chip 10 contacts the first and second electrode 12, 14 by Au bump 72 instead of Ag paste 206 or AuSn eutectic solder and wire 13. The LED chip 10 can be mounted on the insulating substrate 11 with flip chip bonding. So heat releasing from the LED chip 10 may be improved.

### Sixth Embodiment

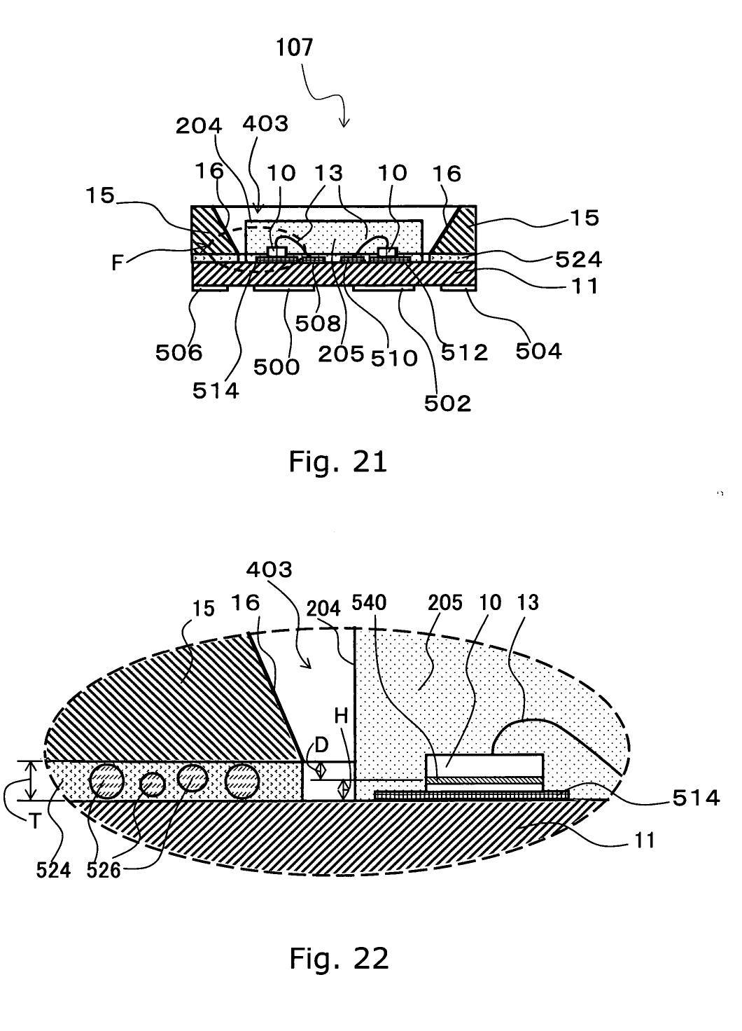

A sixth embodiment of the present invention will be explained hereinafter with reference to FIGS. 20-27. FIG. 21 is a schematic cross sectional view of a semiconductor light emitting device in accordance with the sixth embodiment.

A semiconductor light emitting device 107 is described in accordance with this sixth embodiment of the present invention. With respect to each portion of this embodiment, the same or corresponding portions of the semiconductor light emitting device of the first, second, third, fourth, fifth embodiment or its modified embodiment as shown in FIGS. 1-20 are designated by the same reference numerals, and its explanation of such portions is omitted.

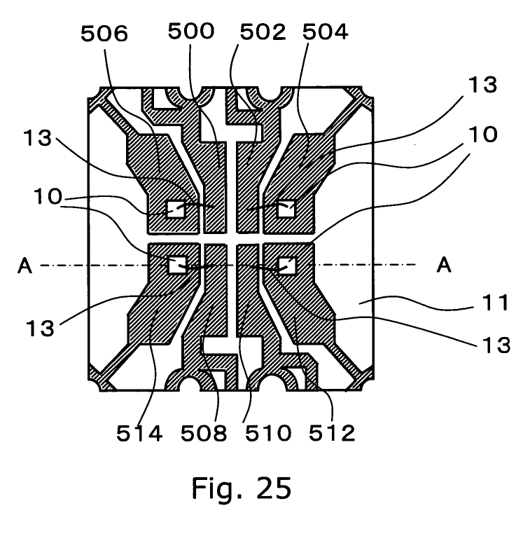

In this embodiment, the metal body 15 and the insulating substrate 11 are adhered with an adhesive 524 having an insulating spacer 526. A detailed explanation of the adhesive 524 and the insulating spacer 526 is described with reference to FIG. 22, which is an enlarged schematic cross sectional view of “F” in FIG. 21. FIG. 21 is a cross sectional view cut along A-A line in FIG. 25.

A reference character “T” in FIG. 22 is a distance from an upper surface of the insulating substrate 11 to the bottom surface of the metal body 15. The “T” is decided by a height of the insulating spacer 526. A reference character “D” is a distance from a horizontal line which divides into halves a thickness of an active layer 540 of the LED chip 10 and the bottom surface of the metal body 15. A reference character “H” in FIG. 22 is a distance from upper surface of the insulating substrate 11 to the horizontal line. Namely T=D+H.

The insulating spacer 526 may be a plastic grain, a silica grain or an alumina grain. The insulating spacer 526 may have a substantially spherical grain and a small distribution of the grain size. However, the insulating spacer 526 is not limited to the substantially spherical grain.

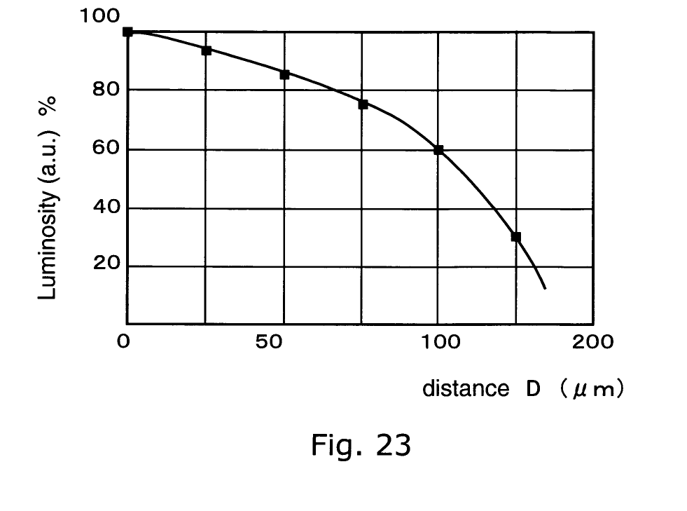

FIG. 23 is a graph showing a relationship a relative luminosity (Y axis) and a distance between a metal body and an active layer (X-axis).

It is assumed a relative luminosity (or luminosity (a.u.) is 100 when the “D” is zero.

The relative luminosity is decreased largely when the “D” is more than 100 micrometers. It is supposed that light emitted from the LED chip 10 or the fluorescent material 205 to horizontal direction does not reached the reflection surface 16. So in such case, it is difficult for light to be emitted from the semiconductor light emitting device 107. It is preferable the “D” is as small as possible in case D≧0.

In case a lowest part of the active layer 540 is provided higher than the bottom surface of the metal body 15, the H>T and D<0. This condition is not depicted in FIG. 23, and light extraction efficiency is improved.

On the other hand, if the “T” is too small, a creepage distance of the adhesive 524 is also small and a dielectric strength is worsened by leaking current in high temperature high humidity condition. The distance “T” is equal to or higher than 50 micrometers regarding manufacturing accuracy of the metal body 15. The dielectric resistance is Mega ohm order which meets a requirement of dielectric strength, equal to or more than 18V. So a range described next is preferable. 50≦T≦(100+H), for instance.

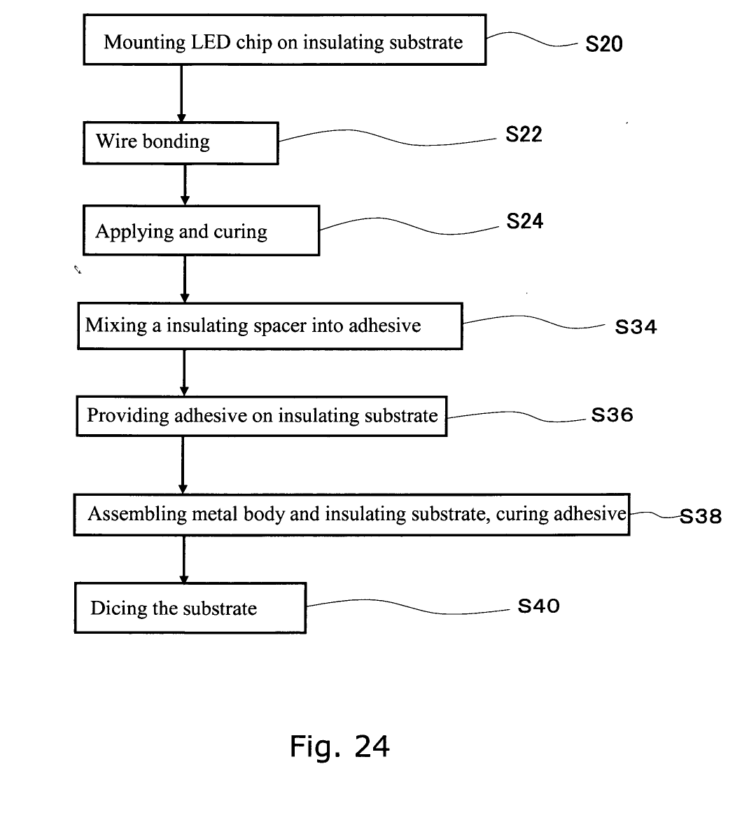

A manufacturing process of the semiconductor light emitting device will be explained hereinafter with reference to FIG. 24-27.

FIG. 24 is a flow chart for manufacturing process of the semiconductor light emitting device in accordance with a sixth embodiment. FIG. 25 is a top view of a semiconductor light emitting device in accordance with a sixth embodiment.

Step S20.

Four pieces of LED chip 10 which has the active layer 540 and is configured to emit blue light are mounted on a third metal portion 504, a fourth metal portion 506, a seventh metal portion 512 and a eighth metal portion 514 of the insulating substrate 11 via AuSb eutectic solder (not shown in FIG. 25) respectively. High luminosity light emitting device is obtained by providing a plurality of LED chip 10 in single light emitting device.

Step S22.

A wire 13 is connected between an upper electrode of LEDs 10 and a first metal portion 500, a second metal portion 502, a five metal portion 508 and a sixth metal portion 510, respectively.

Step S24.

A liquid state sealing resin 204 which contains the fluorescent material 204 is applied on LEDs 10 and the wire 13. The sealing resin 204 is cured. The step S20-S24 is the same as first embodiment.

Step S34

The insulating spacer 526 is mixed into liquid state adhesive 524.

Step S36.

The mixed adhesive 524 is coated on a predetermined portion of the insulating substrate 11 by means of stamping.

Step S38.

The metal body 15 is adjusted to the insulating substrate 11 and the adhesive 524 is heated and cured. A curing condition may be about 30 minutes in 150 Centigrade.

Step S40.

The insulating substrate 11 is separated into individual semiconductor light emitting device. The insulating substrate may be separated with dicing or breaking along a beforehand formed trench on the insulating substrate 11. In case a liquid state adhesive is used as the adhesive 524, the metal body 15 and the insulating substrate 11 are adhered precisely and with good productivity.

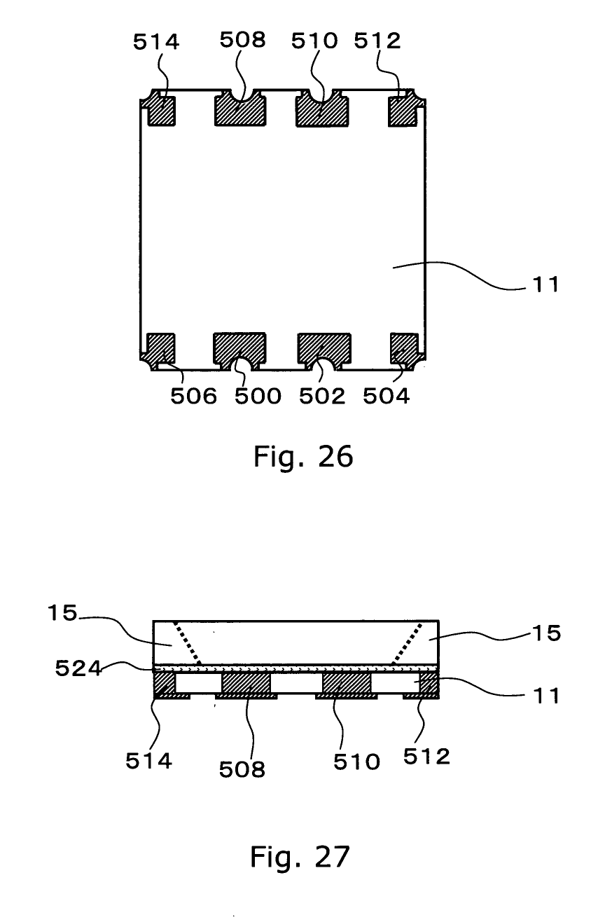

FIG. 26 is a bottom view of a semiconductor light emitting device. Metal portions which are connected the metal portions 500, 502, 504, 506, 508, 510, 512 and 514 is provided on the back surface of the insulating substrate 11.

FIG. 27 is a schematic side view of a semiconductor light emitting device. The metal portion provided on upper surface and the back surface is connected via a metal portion provided on a side of the insulating substrate 11.

In this embodiment, a semiconductor light emitting device which is capable of enduring a temperature of Pb free solder process is obtained by a precise manufacturing process.

### Seventh Embodiment

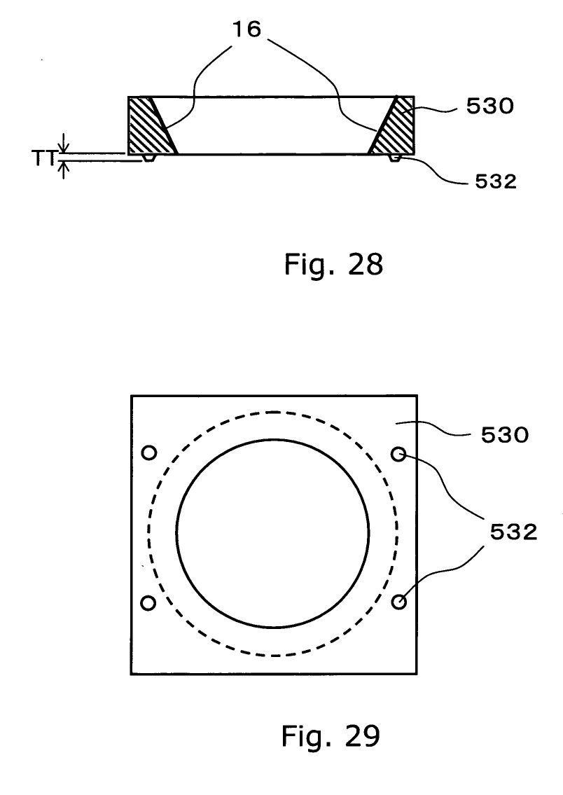

A seventh embodiment of the present invention will be explained hereinafter with reference to FIGS. 28-31. FIG. 28 is a schematic cross sectional view of a metal body 530. FIG. 29 is a schematic bottom view of a metal body 530.

A semiconductor light emitting device 108 is described in accordance with this seventh embodiment of the present invention. With respect to each portion of this embodiment, the same or corresponding portions of the semiconductor light emitting device of the first, second, third, fourth, fifth, sixth embodiment or its modified embodiment as shown in FIGS. 1-27 are designated by the same reference numerals, and its explanation of such portions is omitted.

A protrusion 532 is provided on the bottom surface of the metal body 530. Four protrusions 532 are provided around the through hole. A height “T1” of the protrusion 532 is corresponding to the distance “T” shown in FIG. 22.

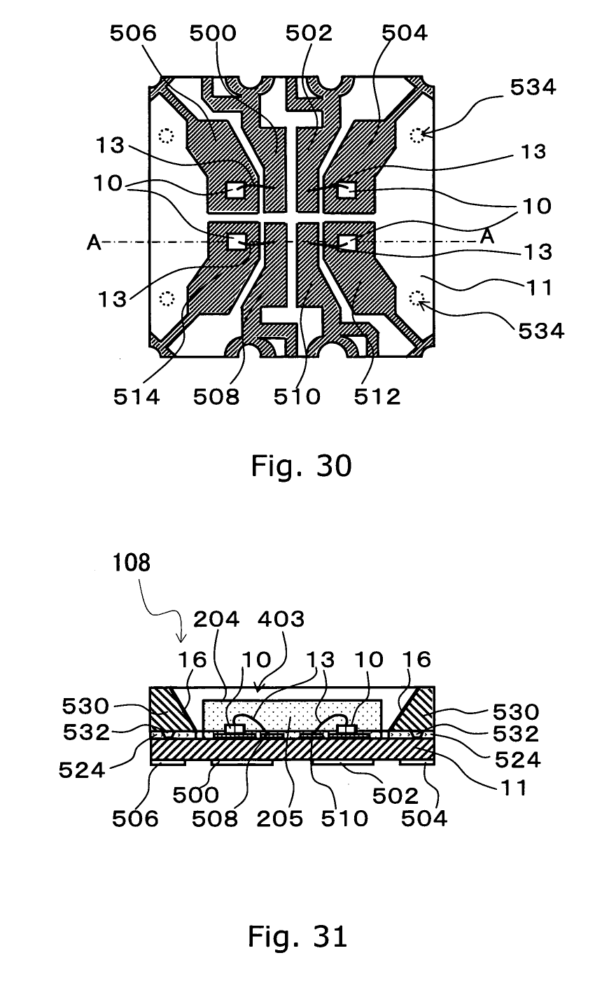

FIG. 30 is a schematic top view of the insulating substrate 11 where four LEDs 10 are mounted. The protrusion 532 is in contact with and the insulating substrate 11 at a contact portion 534, which is circled by broken line in FIG. 30. A metal pattern is not provided on the contact portion 534.

FIG. 31 a cross sectional view taken along A-A line in FIG. 30.

The insulating substrate 11 and the metal body 530 are insulated by the protrusion 534, which is not in contact with a metal pattern of the insulating substrate 11. Alternatively the insulating spacer 526 may be not mixed in the adhesive 524. The distance between the metal body and the insulating layer is kept by the protrusion 534.

As mentioned above in accordance with first-seventh embodiment and modified embodiment, a semiconductor light emitting device which is capable of enduring a temperature of Pb free solder process is obtained.

Other embodiments of the present invention will be apparent to those skilled in the art from consideration of the specification and practice of the invention disclosed herein. It is intended that the specification and example embodiments be considered as exemplary only, with a true scope and spirit of the invention being indicated by the following.

For example, the semiconductor light emitting element is not limited to InAlGaN structure. Other semiconductor light emitting elements are available, such as InGaAlP, GaN, GaAlP and InP by using a III-V compound semiconductor, II-VI compound semiconductor, and so on.

Light emitted from semiconductor light emitting element is not limited to blue or ultraviolet. Other wavelength light is available, such as longer wavelength and visible light, and so on.

A fluorescent material is not limited to yellow phosphor. Other fluorescent materials are available, such as green phosphor, red phosphor and blue phosphor, and so on.

Light emitted from the semiconductor light emitting device is not limited to white light. Other light is available, such as visible light.

Other embodiments of the present invention may be possible by changing the shape, size, material, and positional relations of the ridge waveguide type semiconductor laser device in design by one skilled in the art.

What is claimed is:

1. A semiconductor light emitting device, comprising:
an insulating substrate having an electrode pattern;
a metal body provided on the insulating substrate, the metal body having a through-hole;
an adhesive layer provided between the insulating substrate and the metal body;
a semiconductor light emitting element provided in the through-hole of the metal body, provided on the insulating substrate and electrically connected to the electrode pattern; and
a resin configured to seal the semiconductor light emitting;
wherein an inner surface of the through-hole faces the semiconductor light emitting element, the inner surface has a slanted surface and at least a part of the light emitted from the semiconductor light emitting element is configured to be reflected by the inner surface.

2. A semiconductor light emitting device of claim 1, wherein the metal body has a depression in a peripheral of on a surface which faces the metal body.

3. A semiconductor light emitting device of claim 1, wherein the adhesive layer is configured to insulate from the metal body to the insulating substrate.

4. A semiconductor light emitting device of claim 1, wherein the metal body is electrically connected to the electrode pattern of the insulating substrate.

5. A semiconductor light emitting device of claim 1, wherein the adhesive layer has an insulating spacer.

6. A semiconductor light emitting device of claim 1, wherein a border between the metal body and an adhesive layer is lower than an active layer of the semiconductor light emitting element.

7. A semiconductor light emitting device of claim 1, further comprising:
a metal layer provided on the inner surface of the metal body, the metal layer having higher reflection index in a wavelength of the light emitted from the semiconductor light emitting element.

8. A semiconductor light emitting device of claim 1, wherein the metal body has a protrusion in a surface which faces the metal body.

9. A semiconductor light emitting device, comprising:
an insulating substrate having an electrode pattern;
a metal body provided on the insulating substrate, the metal body having a through-hole;
an adhesive layer provided between the insulating substrate and the metal body;
a semiconductor light emitting element provided in the through-hole of the metal body, provided on the insulating substrate and electrically connected to the electrode pattern; and
a resin configured to seal the semiconductor light emitting;
wherein an inner surface of the through-hole faces the semiconductor light emitting element, the inner surface of the through-hole has a first slanted surface and a second slanted surface, the second slanted surface is larger in an angle from the than the first slanted surface, and at least a part of the light emitted from the semiconductor light emitting element is configured to be reflected by the inner surface.

10. A semiconductor light emitting device of claim 9, wherein the metal body has a depression in a peripheral of on a surface which faces the metal body.

11. A semiconductor light emitting device of claim 9, wherein a border between the metal body and an adhesive layer is lower than an active layer of the semiconductor light emitting element.

12. A semiconductor light emitting device of claim 9, wherein the adhesive layer has an insulating spacer.

13. A semiconductor light emitting device of claim 9, further comprising, a metal layer provided on the inner surface of the metal body, the metal layer having higher reflection index in a wavelength of the light emitted from the semiconductor light emitting element.

14. A semiconductor light emitting device of claim 9, wherein a position where the second slanted surface is provided is higher than a position where the first slanted surface is provided.

15. A semiconductor light emitting device, comprising:
an insulating substrate having an electrode pattern;
a metal body provided on the insulating substrate, the metal body having a through-hole;
an adhesive layer provided between the insulating substrate and the metal body;
a semiconductor light emitting element provided in the through-hole of the metal body, provided on the insulating substrate and electrically connected to the electrode pattern; and
a resin configured to seal the semiconductor light emitting resin;
wherein an inner surface of the through-hole faces the semiconductor light emitting element, the inner surface of the through-hole has an downward convex envelope in a cross sectional view and at least a part of the light emitted from the semiconductor light emitting element is configured to be reflected by the slanted surface.

16. A semiconductor light emitting device of claim 15, wherein the metal body has a depression in a peripheral of on a surface which faces the metal body.

17. A semiconductor light emitting device of claim 15, wherein a border between the metal body and an adhesive layer is lower than an active layer of the semiconductor light emitting element.

18. A semiconductor light emitting device of claim 15, wherein the adhesive layer has an insulating spacer.

19. A semiconductor light emitting device of claim 15, further comprising:
a metal layer provided on the inner surface of the metal body, the metal layer having higher reflection index in a wavelength of the light emitted from the semiconductor light emitting element.

20. A semiconductor light emitting device of claim 15, wherein the metal body is made of Al.
